(19) United States
(12) Patent Application Publication
(10) Pub. No.: US 2015/0241486 A1
(43) Pub. Date: Aug. 27, 2015

(54) CONTROLLER TO DETERMINE A RISK OF THERMAL DAMAGE BASED ON CURRENT MEASUREMENTS

(71) Applicants: Scott T Christensen, Houston, TX (US); Chanh V Hua, Houston, TX (US); Larry G Keller, Houston, TX (US); Leopoldo Alaniz, Spring, TX (US); Peter Andrew VanNess, Cypress, TX (US)

(72) Inventors: Scott T Christensen, Houston, TX (US); Chanh V Hua, Houston, TX (US); Larry G Keller, Houston, TX (US); Leopoldo Alaniz, Spring, TX (US); Peter Andrew VanNess, Cypress, TX (US)

(21) Appl. No.: 14/424,030

(22) PCT Filed: Aug. 29, 2012
(86) PCT No.: PCT/US2012/052775

§ 371 Date: Feb. 25, 2015

(51) Int. Cl. G01R 21/00; G01N 27/14

(52) U.S. Cl. CPC G01R 21/006; G01N 27/14

(57) ABSTRACT

Examples disclose a system with an input current sensing circuit to measure an input current of a current carrier. Additionally, the examples disclose an output sensing circuit to measure an output current from the current carrier. Further, the examples disclose a controller to determine a power loss associated with the current carrier based on the input and the output current measurements. The power loss indicates a risk of a thermal damage to the current carrier.

### BACKGROUND

Increasing thermal temperatures of a power distribution system may cause thermal damage within the system. The damage may cause catastrophic failures and other issues such as hardware damage, safety hazards, and loss of efficiency.

### BRIEF DESCRIPTION OF THE DRAWINGS

In the accompanying drawings, like numerals refer to like components or blocks. The following detailed description references the drawings, wherein:

FIG. 1 is a block diagram of an example controller with an input and an output sensing circuit for the controller to determine a power loss and identify a risk of thermal damage of a current carrier;

FIG. 2 is a block diagram of an example controller to determine a power loss and identify a risk of thermal damage based on current measurements of a current carrier from an input and an output sensing circuit, the current carrier receives power from a power supply, and the controller manages a circuit breaker to prevent thermal damage to a load with a server;

FIG. 3 is a data arrangement of an example table including resistance, voltage, and power loss of a busbar with a corresponding risk of thermal damage;

FIG. 4 is a flowchart of an example method performed by a computing device to receive input and output current measurements, convert the measurements to digital measurements, and determine a risk of thermal damage by comparing the measurements; and

FIG. 5 is a block diagram of an example computing device with a processor to receive input and output current measurements, determine a difference between the measurements, and identify the risk of thermal damage to a busbar.

### DETAILED DESCRIPTION

Thermal temperature increases may cause failures and other issues within a power distribution system. One solution provides a temperature sensor to detect heat within the system. This solution uses a thermal sensor within a circuit assembly to monitor and detect a thermally destructive event. However, the thermal sensor measures thermal temperature from a single point within the circuit assembly rather than of the assembly as a whole. For example, a controller may monitor a circuit assembly by receiving temperature measurements regarding specific points surrounding the temperature sensor on the assembly. However, this solution is limited in monitoring the temperature as it monitors only areas surrounding the sensor rather than monitoring the full assembly. Additionally, the solution may not be accurate for the full circuit assembly as it monitors only specific points.

In another solution, current and/or power measurements are provided to monitor the circuit assembly. In this solution, measurements may be taken and provided to a controller to monitor damage caused by thermal temperatures. For example, power measurements may indicate hardware failures, thus the controller monitors once the circuit assembly suffers thermal damage. However, this solution does not monitor thermal temperatures in real-time, rather it monitors once the damage has occurred. Additionally, this solution is inefficient as it may not prevent thermal damage. Further, both of these solutions are inefficient as the solutions monitor thermal temperatures without taking further action when the temperature is close to causing damage.

To address these issues, example embodiments disclosed herein provide a system with an input sensing circuit and an output sensing circuit that provides input and output current measurements of a busbar to a controller. The busbar is part of a power distribution system that carries current (i.e., conducts electricity) from one electrical component to another Measuring the input and the output current of the busbar within the power distribution system enables efficient and effective monitoring of the internal temperatures of the busbar to prevent damage within the system. Further, measuring the input and output current of the busbar provides accurate monitoring of the circuit as a whole.

Additionally, this example embodiment the controller identifies a risk of thermal damage within the busbar based on a difference between the input and the output current measurements. Identifying the risk of thermal damage, enables the controller to prevent thermal damage to the circuit and/or power system. For example, the controller may determine the busbar has a higher risk of thermal damage and transmit a signal to an electrical component within the power system to disconnect. The current measurements are provided in real-time to enable the controller to monitor a particular risk of thermal damage. Additionally, identifying the risk of thermal damage prevents energy losses by detecting a potential thermal event. In this embodiment, action may be taken to prevent any further energy losses. The risk of thermal damage indicates the likelihood the busbar experiences a temperature increase signifying issues that may jeopardize the integrity of the busbar. For example, such issues may include hardware damage, material imperfections, poor electrical connections, short-circuit, high resistivity, poor manufacturing, or other issues that jeopardize the integrity of the busbar and/or power system.

In another embodiment, the system includes a circuit breaker connected to the controller. The circuit breaker interrupts the flow of current from the busbar to a load. The controller may interrupt the flow of current once identifying a high risk of thermal damage to a busbar. Interrupting the flow of current through the circuit breaker enables the controller to prevent thermal damage to the power system. This embodiment provides efficiency as the controller may prevent thermal damage.

In a further embodiment, once determining the power loss indicating the risk of thermal damage, the controller performs at least one of: transmitting a notification of the thermal damage, interruptting the flow of current from the busbar to a load, and throttling a server within the load to reduce the output current delivered to the load. This embodiment provides additional efficiency as the controller may manage the system based on the identification of the risk of thermal damage. For example, the controller may determine the risk of thermal damage is low indicating no threat of thermal damage and transmit a notification to an administrator updating the risk of thermal damage.

Yet, in a further embodiment, the controller receives the input and output current measurements as analog waveforms. The controller then converts the analog measurements to digital measurements. Receiving the current measurements as analog waveforms provides real-time measurements of the busbar to further prevent thermal damage of the system. Additionally, converting the input and output current measurements to digital measurements enables the controller to compare the measurements to readily identify differences.

In summary, example embodiments disclosed herein provide efficient and effective monitoring of internal temperatures within a busbar to prevent thermal damage within a power system. Further, example embodiments disclosed herein effectively manages the power system to further prevent thermal damage based on the identification of the risk of the thermal damage.

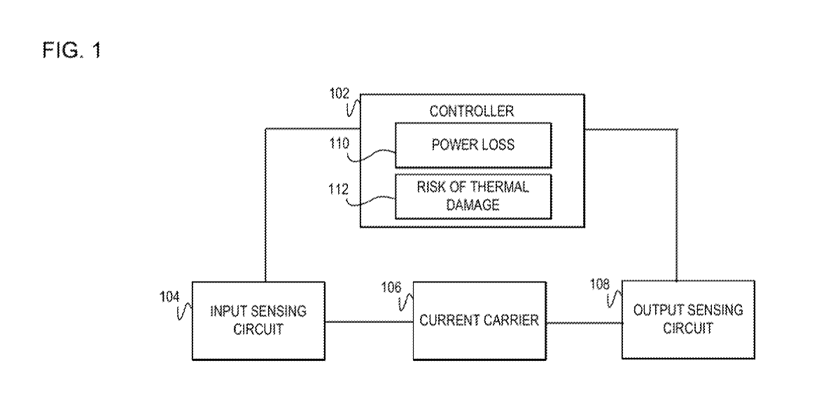

Referring now to the drawings, FIG. 1 is a block diagram of an example controller 102 including module 110 and module 112 to receive an input and an output current measurement of a current carrier 106 from an input sensing circuit 104 and an output sensing circuit 108, respectively. Embodiments of the controller 102 include a microchip, chipset, electronic circuit, processor, microprocessor, semiconductor, microcontroller, processor, central processing unit (CPU), graphics processing unit (GPU), visual processing unit (VPU), or other programmable device capable of receiving current measurements of the current carrier 106 from the input sensing circuit 104 and the output sensing circuit 108 to determine the power loss at module 110 and identify a risk of thermal damage of the current carrier 106 at the module 112.

The input sensing circuit 104 is electronic measuring component that detects input current as delivered to the current carrier 106 and provides a measurement of the input current to the controller 102. The input current measurement of the current carrier 106 is a communication provided by a signal, bit, or data representing the magnitude of the input current received by the current carrier 106. In an embodiment, the input current measurement is provided by an analog waveform from the input sensing circuit 104 to the controller 102. In another embodiment, a power supply delivers power to the input sensing circuit 104 which converts the power to the input current of the current carrier 106. This embodiment is explained in detail in a later figure. Embodiments of the input sensing circuit 104 include a meter, multimeter, ohmmeter, electromechanical meter, electricity meter, power meter, resistance measuring component, current meter, voltmeter, or other type of electronic measuring component capable of detecting input current to a current carrier 106 and providing a current measurement to the controller 102.

The current carrier 106 conducts electricity between electrical components within a power system. Specifically, the current carrier 106 may include the connections (i.e., contacts) between the electrical components and includes a type of metal to provide current between the electrical components. Providing electricity between the electrical components enables the components to perform the various tasks within the power system. For example, the current carrier 106 may provide current to a server for networking tasks. Embodiments of the current carrier 106 include a busbar, metal strip, electrical contact, current structure, or other type of current carrier 106 capable of providing current between electrical components.

The output sensing circuit 108 is electronic measuring component that detects the output current from the current carrier 106 and as such, delivers the output current measurement to the controller 102. The output current measurement of the current carrier 106 is a communication provided by a signal, bit, or data representing the magnitude of the output current of the current carrier 106. In an embodiment, the output current measurement is provided as an analog waveform from the output sensing circuit 108 to the controller 102. In another embodiment, the output sensing circuit 108 receives output current from the current carrier 106 that is delivered to a load (i.e., not pictured) which includes one or more servers. In this embodiment, the output sensing circuit 108 measures the output current from the current carrier 106 within the power distribution system, namely a power server system. In a further embodiment, the output sensing circuit 108 includes a circuit breaker for the controller 102 to signal an interruption of the flow of current from the current carrier 106. This embodiment is explained in detail in the next figure. Embodiments of the output sensing circuit 108 include a meter, multimeter, ohmmeter, electromechanical meter, electricity meter, power meter, resistance measuring component, current meter, voltmeter, or other type of electronic measuring component capable of detecting output current of a current carrier 106 and providing the current measurement to the controller 102.

At module 110, the controller determines the power loss between the input and output current measurements of the current carrier 106. In one embodiment, module 110 includes the controller 102 determining the difference between the input and the output current measurements to identify the power loss. In another embodiment, module 110 includes determining the difference between the input and output current measurements of the current carrier 106 and calculating the resistance from the difference. In a further embodiment, module 110 receives the current measurements as analog measurements and converts the measurements to digital measurements. This is embodiment is explained in detail in a later figure. Embodiments of module 110 include a set of instructions, instruction, process, operation, logic, algorithm, technique, logical function, firmware, and or software executable by the controller 102 to determine a power loss based on the input current measurements from sensing circuits 104 and 108.

At module 112, the risk of thermal damage is identified based on the power loss as determined at module 110. The risk of thermal damage to the current carrier 106 indicates the likelihood of a thermal event that may cause damage to the current carrier 106 and/or power system. The thermal damage risks may include low, acceptable, moderate, and/or high to indicate the likelihood of damage. For example, the risk of low indicates the current carrier 106 is operating within the range of ideal temperatures, while the high risk indicates the current carrier 106 has a greater likelihood to be experiencing a thermal event (i.e., the current carrier is operating outside of the range of ideal temperatures). Embodiments of module 112 include a set of instructions, instruction, process, operation, logic, algorithm, technique, logical function, firmware, and or software executable by the controller 102 to identify the risk of thermal damage to the current carrier 106 based on the power loss determined at module 110.

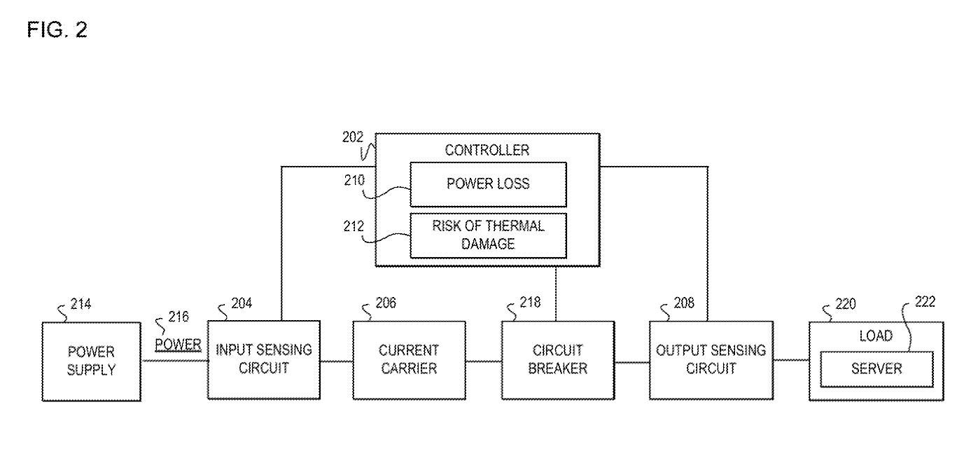

FIG. 2 is a block diagram of an example controller 202 to determine a power loss at module 210 based on a difference of current measurements between an input sensing circuit 204 and an output sensing circuit 208. The controller 202 identifies a risk of thermal damage to a current carrier 206 at module 212. The current carrier 206 receives power 216 from a power supply 214 and the controller 202 further manages a circuit breaker 218 to prevent thermal damage to a load 220 with a server 222. The controller 202, the input sensing circuit 204, the current carrier 206, and the output sensing circuit 208 may be similar in structure and functionality to the controller 102, the input sensing circuit 104, the current carrier 106, and the output sensing circuit 108 as in FIG. 1.

The module 210 determines the power loss based on a difference between the input and output current measurements of the current carrier 206 as provided by the input and output sensing circuits 204 and 208, respectively. The module 212 identifies the risk of thermal damage as based on the power loss determined at module 210. In one embodiment, the greater the power loss, the greater the risk, and the greater the likelihood of thermal damage to the current carrier 206. For example, the power loss may be higher than a threshold range, thus this indicates the higher risk of thermal damage to the current carrier 106. The modules 210 and 212 may be similar in functionality to the modules 110 and 112 and in FIG. 1.

The power supply 214 supplies power 216 through the input sensing circuit 204 to produce or provide the input current to the current carrier 206. Embodiments of the power supply 214 include a power feed, power source, generator, power circuit, energy storage, electromechanical system or other type of power supply capable of supplying electrical energy through the input sensing circuit 204 to the current carrier 206.

The power 216 provides electrical energy through the input sensing circuit 204 to the current carrier 206 to supply the load 220. The power 216 is provided from the power supply 214 to provide energy through the current carrier 206 to electrical components within a power system in order to perform various tasks. For example, the current carrier 206 delivers current to the controller 202 to perform clock speeds or logical functions. Embodiments of the power 216 include watts, current, electrical change, watts, alternating current, direct current, voltage, analog voltage, digital voltage, or other type energy capable of being supplied to the input sensing circuit 204 to provide the input current measurement to the controller 202.

The circuit breaker 218 is an electrical component managed by the controller 202, located between the current carrier 206 and the load 220, to interrupt the flow of output current from the current carrier 206 to the load 220. Specifically, the circuit breaker 218 functions to connect and/or disconnect by interrupting or continuing the flow of output current to the load 220. In this embodiment, the circuit breaker 218 is used to protect the load 220 and/or server 222 if the risk of thermal damage to the current carrier 206 is high. For example, the current carrier 206 may be experiencing over-current and this may potentially damage the load 220 and/or server 222 so the controller 202 may prevent the damage by interrupting the flow of the the output current of the current carrier 206 to the load 220 and/or server 222. In an embodiment, the circuit breaker 218 is part of the output sensing circuit 208, while in another embodiment, the circuit breaker 218 is physically separated from the output sensing circuit 208. Embodiments of the circuit breaker 218 include a switch, electrical circuit, semiconductor, relay, residual-current device, autorecloser, or other type of electrical component capable of interrupting the flow of the output current from the current carrier 206 to the load 220.

The load 220 is part of the power distribution system and receives output current through the current carrier 206 and/or power derived from the output current of the current carrier 206. In one embodiment, the load 220 includes the server 222, while in a further embodiment, the load 220 includes a distribution system to more than one server 222. In a further embodiment, the load 220 receives power as derived from the output current of the current carrier 206. In this embodiment, a conversion component is located between the circuit breaker 218 and the load 220 to convert the output current of the current carrier 206 to power received by the load 220. Embodiments of the load 220 include an electrical circuit, electrical impedance, servers, computing devices, or other type of circuit capable of receiving output current and/or power through the current carrier 206.

The server 222 provides services across a network and is located within the power system. The server 222 is included as part of the load 220 may include one or more servers 222. Embodiments of the server may include a computing device, a web server, network server, an enterprise server, a Local Area Network (LAN) server, a print server, or any other computing device capable as part of the load 220 to provide services across a network.

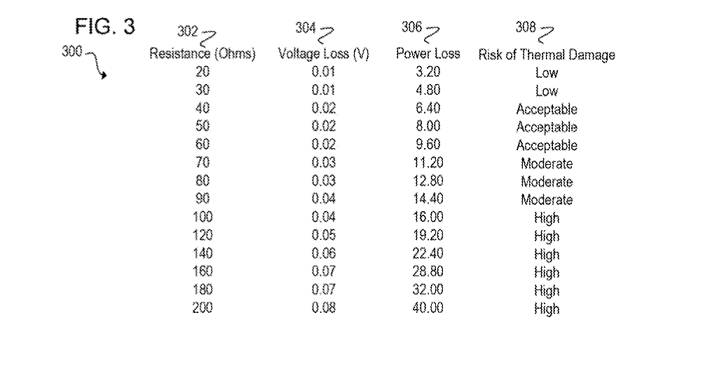

FIG. 3 is a data arrangement of an example table 300 associated with a busbar including a resistance 302, voltage loss 304, power loss 306 of the busbar, and a corresponding risk of thermal damage 308. As depicted in FIG. 3, table 300 illustrates the higher resistance 302, the higher voltage loss 304, and the higher power loss 306 indicates the greater the risk of thermal damage 308 within the busbar. Although the table 300 illustrates the resistance 302, the voltage loss 304, the power loss 306, and the risk of thermal damage 308, embodiments should not be restricted this illustration, as the table 300 may include any single data component 302, 304, 306, or 308 and/or combination of data components 302, 304, 306, and 308. For example, the table 300 may include the resistance 302 corresponding to the risk of thermal damage 308 to determine the likelihood the busbar is to experience a thermal event.

The resistance 302 is measurement of opposition an input current experiences through a current carrier (i.e., busbar). In one embodiment, the resistance 302 is calculated based on an input and output current measurements provided by sensing circuits to a controller. In one embodiment, the resistance 302 may include a threshold range between 20-60 ohms of which the corresponding risk 308 would be minimal (i.e., low and/or acceptable). For example, above 60 ohms, the corresponding risk 308 increases to moderate and/or high indicating a greater likelihood of damage. Although FIG. 3 illustrates the resistance 302 in ohms, this was done for illustration purposes and not for limiting embodiments. For example, the resistance 302 may include other units of resistance, such as volts/amperes.

The voltage loss 304 is considered a drop of voltage across the busbar. The voltage loss 304 is considered a type of electrical energy that may be lost and/or dissipates within the busbar. In one embodiment, the voltage loss may include a threshold range of which the risk of thermal damage 308 would be minimal. For example, FIG. 3 depicts the threshold of voltage loss 304 between 0.01 V to 0.02 as a low risk to acceptable risk. This signifies the busbar is less likely to experience any thermal events and/or integrity issues. In another embodiment, the voltage loss 304 may be determined based on the difference between the input and output current measurements of the busbar.

The power loss 306 is the rate at which electrical energy is lost within the busbar. In one embodiment, the power loss 306 includes a threshold range between 3.20 to 9.60, which indicates the corresponding risk 308 is minimal. In this embodiment, once the power loss 306 increases above the threshold range to 11.20, the risk of thermal damage is a higher (i.e., moderate and/or high) indicating the likelihood of thermal damage. In another embodiment, the voltage loss 304 may be determined based on the difference between the input and output current measurements of the busbar. Embodiments of the power loss include a watt, volt, joule, amperes, ohms, or other type of power representing the loss of electrical energy within the busbar.

The risk of thermal damage 308 indicates the likelihood the busbar is to experience the thermal event which may potentially damage the busbar. For example, the increase in resistance 302 of the busbar raises the thermal temperature of the busbar. Rather than using temperatures, the controller utilizes current measurements from the bus bar to obtain the data components 302, 304, and 306 to monitor the internal temperature of the busbar through the risk of thermal damage. In this regard, the risk of thermal damage 308 is based on each of the data components 302, 304, and 306. In another embodiment, the risk of thermal damage 308 is based on a difference between the current measurements of the busbar (i.e., not pictured) as provided to the controller. The risk of thermal damage indicates the likelihood the busbar experiences the thermal event. The thermal event represents an increase of temperature that is symptomatic of issues with the busbar. Such issues include oxidation, higher resistivity, hardware damage, short-circuit, over-current, poor manufacturing, material imperfections, poor electrical connections, and other issues that jeopardize the integrity of the busbar and/or power system.

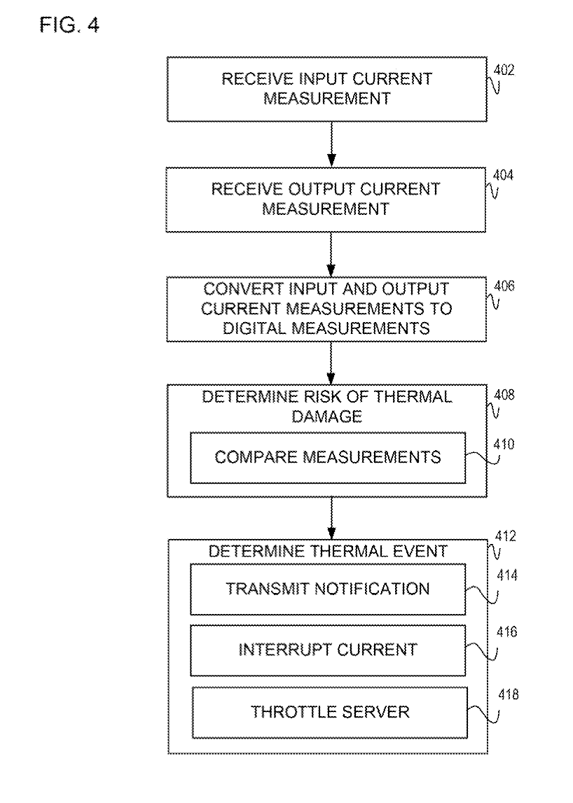

FIG. 4 is a flowchart of an example method performed by a computing device to receive input and output current measurements, convert the measurements to digital measurements, and determine a risk of thermal damage by comparing the measurements. Although FIG. 4 is described as being performed on the computing device, it may also be executed on other suitable components as will be apparent to those skilled in the art. For example, FIG. 4 may be implemented in the form of executable instructions stored on a machine-readable storage medium or on a controller 102 and 202 as in FIGS. 1-2 or in the form of electronic circuitry.

At operation 402, the computing device receives the input current measurement of a busbar. In one embodiment of operation 402, a converter receives power to convert into the input current measurement for the computing device to receive.

At operation 404, the computing device receives the output current measurement of the busbar. In one embodiment of operations 402 and 404, the computing device receives the current measurements as analog waveforms representing the magnitudes of the input current and the output current, respectively. In this embodiment, the waveforms are received in real-time measuring the input and output current and thus enabling the computing device to monitor the busbar in real-time. In another embodiment, the current measurements at operations 402 and 404 may be received periodically to identify a risk of thermal damage at operation 408.

At operation 406, the computing device converts the input and output current measurements received at operations 402 and 404 to digital measurements. In this embodiment, converting the current measurements to digital measurements enables the computing device to compare the measurements at operation 410 to readily identify the difference between the measurements. Once determining the difference between the current measurements, the computing device determines the risk of thermal damage at operation 408.

At operation 408, the computing device identifies the risk of thermal damage of the busbar. In an embodiment of operation 408, the computing device determines the power loss, such as voltage loss and/or current loss of the current measurements received at operations 402 and 404 to determine the corresponding risk of thermal damage of the busbar. In another embodiment of operation 408, the computing device determines the difference between the current measurements received at operations 402 and 404. In this embodiment, the computing device determines the resistance from the difference to identify the corresponding risk of thermal damage.

At operation 410, the computing device compares the current measurements received at operations 402 and 404 to identify the risk of thermal damage of the busbar at operation 408. In an embodiment of operation 410, the computing device determines the difference of the current measurements received at operations 402 and 404 by comparing the current measurements.

At operation 412, the computing device determines whether a thermal event may occur based on the risk of thermal damage at operation 408. In one embodiment, once determining the thermal event at operation 412, the computing device performs at least one of: transmit notification at operation 414, interrupt the flow of current from the busbar to a load at operation 416, and throttle a server within the load at operation 418. In another embodiment of operation 412, the computing device may determine the risk of thermal damage to the busbar is high and thus perform operations 416 and/or 418. In a further embodiment of operation 412, if the risk of thermal damage is minimal (i.e., low and/or acceptable), the computing device may perform operation 414.

At operation 414, the computing device transmits a notification once determining the risk of thermal damage at operation 408. Embodiments of operation 414 include an email, display, administrator interface, or other type of notification that is transmitted. In another embodiment of operation 414, the notification may include the risk of thermal damage as determined at operation 408. Transmitting a notification at operation 412, provides an administrator with data concerning the risk of thermal damage of the busbar.

At operation 416, the computing device interrupts the flow of current from the busbar to a load. In this embodiment, the computing device communicates with a circuit breaker to interrupt the flow of current between the busbar and the load. This embodiment prevents further damage to the load by interrupting the flow of current. In an embodiment of operation 416, once determining the risk of thermal damage is higher at operation 408, the computing device determines the internal temperature of the busbar is increasing indicating the thermal event jeopardizing the intergrity of the busbar, the computing device interrupts the flow of current to the load and/or communicates with the load to throttle the server at operation 418. For example, the busbar may suffer hardware damage, thus the difference between the current measurements may increase over time, indicating the integrity of the busbar is at issue. Thus, the computing device determines the high risk of thermal damage to the busbar, and interrupts the flow of current at operation 416 and/or throttles the server within the load at operation 418 to prevent thermal damage to the load.

At operation 418, the computing device may communicate with the load to throttle a server within the load. In this embodiment, the output current delivered to the load may be reduced by throttling the server within the load. This further prevents damage within the load and/or server.

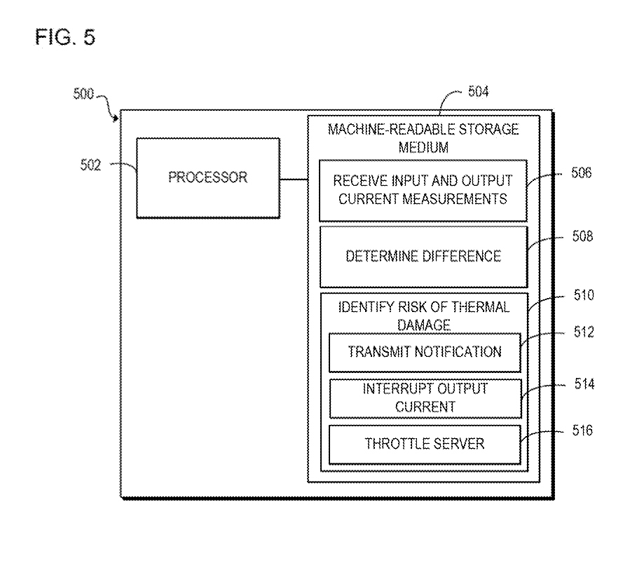

FIG. 5 is a block diagram of an example computing device 500 with a processor 502 to receive input and output current measurements of a busbar, determine a difference between the measurements to identify a risk of thermal damage to the busbar. Although the computing device 500 includes processor 502 and machine-readable storage medium 504, it may also include other components that would be suitable to one skilled in the art. For example, the computing device 500 may include the controller as in FIG. 1. Embodiments of the computing device 500 include a client device, personal computer, desktop computer, laptop, a mobile device, or other computing device suitable to include components 502 and 504.

The processor 502 may fetch, decode, and execute instructions 506, 508, 510, 512, 514 and 516. Embodiments of the processor 502 may include a controller, microchip, chipset, electronic circuit, processor, microprocessor, semiconductor, microcontroller, processor, central processing unit (CPU), graphics processing unit (GPU), visual processing unit (VPU), or other programmable device receiving input and output current measurements of a busbar. The processor 502 executes instructions to: receive input and output current measurements of the busbar instructions 506, determine a difference between the current measurements instructions 508, identify a risk of thermal damage to the busbar instructions 510, and once determining a thermal event, the processor 502 performs at least one of: transmit a notification instructions 512, interrupt the flow of output current to a load instructions 514, and throttle a server within the load instructions 516.

The machine-readable storage medium 504 may include instructions 506-516 for the processor 502 to fetch, decode, and execute. The machine-readable storage medium 504 may be an electronic, magnetic, optical, memory, flash-drive, or other physical device that contains or stores executable instructions. Thus, the machine-readable storage medium 504 may include for example, Random Access Memory (RAM), an Electrically Erasable Programmable Read-Only memory (EEPROM), a storage drive, a memory cache, network storage, a Compact Disc Read Only Memory (CD-ROM) and the like. As such, the machine-readable storage medium 504 can include an application and/or firmware which can be utilized independently and/or in conjunction with the processor 502 to fetch, decode, and/or execute instructions on the machine-readable storage medium 504. The application and/or firmware can be stored on the machine-readable storage medium 504 and/or stored on another location of the computing device 500.

In summary, example embodiments disclosed herein provide monitoring a thermal temperature within a busbar to prevent thermal damage by identifying a risk of the thermal damage, increasing efficiency of a power system. Further, example embodiments disclosed herein effectively manages resources within the power system by taking action to prevent thermal damage.

We claim:

1. A system comprising:
an input current sensing circuit to measure an input current of a current carrier;
an output current sensing circuit to measure an output current from the current carrier; and
a controller to determine a power loss associated with the current carrier based on the input and output current measurements, the power loss indicating a risk of a thermal damage to the current carrier.

2. The system of claim 1 further comprising:
a circuit breaker, connected to the controller, to interrupt the output current distributed to a server from the current carrier.

3. The system of claim 1 further comprising:
a load connected to the current carrier to receive the output current, the load including a server.

4. The system of claim 1 wherein the controller determines the power loss associated with the current carrier indicating the risk of thermal damage by obtaining a difference between the input and the output current measurements.

5. The system of claim 1 wherein a greater power loss corresponds to a higher risk of thermal damage to the current carrier.

6. The system of claim 1 wherein the controller determines the power loss associated with the current carrier by calculating a resistance of the current carrier based on the input and output current measurements.

7. The system of claim 1 wherein the controller, upon determining the power loss indicating the risk of thermal damage, performs at least one of: transmitting a notification of the thermal damage, interrupting the output current from the current carrier to a load; and throttling a server within the load to reduce the output current delivered to the load from the current carrier.

8. The system of claim 1 wherein the current carrier comprises a type of metal and delivers current to a server distribution system, the system of claim 1 further comprising:
a power supply to deliver power to the input sensing circuit.

9. A method executed by a computing device, the method comprising:
receiving an input current measurement of a busbar;
receiving an output current measurement the busbar; and
determining a risk of thermal damage to the busbar based on a difference between the input and the output current measurements.

10. The method of claim 9 wherein the input and the output current measurements are received as analog current waveforms and the method is further comprising:
converting the input and the output current measurements to digital measurements to determine the difference.

11. The method of claim 9 further comprising wherein determining the risk of thermal damage to the busbar based on the difference between the input and the output current measurements, is further comprising:
comparing the input current measurement and the output current measurement to determine the difference and wherein the difference represents a power loss associated with the current carrier indicating the risk of the thermal damage.

12. The method of claim 9 wherein a greater difference between the current measurements corresponds to a higher risk of thermal damage to the busbar, the method is further comprising:
performing at least one of: transmitting a notification of the higher risk, interrupting the output current from the current carrier to a load; and throttling a server within the load to reduce the output current delivered to the load from the current carrier.

13. A non-transitory machine-readable storage medium encoded with instructions executable by a processor of a computing device, the storage medium comprising instructions to:
receive an input current measurement and an output current measurement of a busbar;
determine a difference between the input and the output current measurements to obtain a resistance of the busbar;
based on the resistance, identify a risk of thermal damage associated with the busbar.

14. The non-transitory machine-readable storage medium including the instructions of claim 13, further comprising instructions to:
upon identification of the risk of thermal damage, the computing device performs at least one of the instructions to: transmit a notification of the risk of thermal damage, interrupt the output current from the busbar to a load; and throttle a server within the load to reduce the output current delivered to the load from the busbar.

15. The non-transitory machine-readable storage medium including the instructions of claim 14 wherein the input and the output current measurements are received as analog measurements in real-time.
